(19) United States
(12) Patent Application Publication
(10) Pub. No.: US 2013/0088268 A1
(43) Pub. Date: Apr. 11, 2013

(54) Multi-Phase Clock Generation System and Clock Calibration Method Thereof

(71) Applicants: Ruo-Ting Ding, New Taipei City (TW); Shi-Yu Huang, Luzhu Township (TW); Chao-Wen Tzeng, Taichung CIty (TW)

(72) Inventors: Ruo-Ting Ding, New Taipei City (TW); Shi-Yu Huang, Luzhu Township (TW); Chao-Wen Tzeng, Taichung CIty (TW)

(73) Assignee: TINNOTEK INC., Hsinchu City (TW)

(21) Appl. No.: 13/342,729

(22) Filed: Jan. 3, 2012

(30) Foreign Application Priority Data
Oct. 5, 2011 (TW) 100136178

(51) Int. Cl. H03B 19/00

(52) U.S. Cl. 327/117

(57) ABSTRACT

A multi-phase clock generation system and a clock calibration method thereof. The multi-phase clock generation system comprises an input module, a frequency division module and a control module. The input module inputs a reference clock signal with a clock period. The frequency division module according to the reference clock signal produces a phase clock signal with a frequency magnification relationship. The control module divides the phase clock signal into a plurality of clock intervals. There is a clock interval between two adjacent phase clock signals, and each of the plurality of clock intervals has a phase time delay. The control module controls a first phase clock signal of the plurality of phase clock signals to align with a last phase clock signal. The control module sequentially arranges each of the plurality of phase clock signals according to the phase time delay.

### CROSS-REFERENCE TO RELATED APPLICATION

This application claims the benefit of priority to Taiwan Patent Application No. 100136178, filed on Oct. 5, 2011, in the Taiwan Intellectual Property Office, the disclosure of which is incorporated herein in its entirety by reference.

### BACKGROUND OF THE INVENTION

1. Field of the Invention

The present invention relates to a clock generation system, in particular to a multi-phase clock generation system capable of generating multi-phase clocks accurately and a clock calibration method thereof.

2. Description of the Related Art

As science and technology advance and the speed of transmitting data becomes increasingly faster, the processing speed of central processing units also becomes faster and faster. In general, a multi-phase clock is usually applied in a sequence reduction circuit, a phase/frequency modulation circuit and a sequence interlace circuit, and the performance of the circuit is mainly determined by the resolution of the multi-phase clock. In other words, the performance of the system depends on the quantity and precision of the multi-phase clock.

At present, most multi-phase clock generators (MPCG) are comprised of a delay-locked loop (DLL) or a voltage control oscillator (VCO) as shown in FIG. 1, which shows a conventional multi-phase clock generator. In FIG. 1, four tunable delay elements (TDE) 91 with digital adjustable codes are combined. With reference to FIG. 2 for a schematic view of a conventional tunable delay element, the overall delay will be increased, thus causing an extended duty cycle if a signal passing through a plurality of buffer gates 94. The clock pulse will disappear completely if the signal passes through too many buffer gates 94. For example, if a signal passes through one buffer gate in a 0.18 um-manufacturing process, the pulse of the signal may be extended to approximately 10 ps. Therefore, if an input of clock period is equal to 1600 ps and the duty cycle is equal to 50%, the clock pulse will disappear completely after the signal passes through 80 buffer gates 94. Thus, the conventional tunable delay element (TDE) 91 may result in a completely disappearance of signal pulse. Since each tunable delay element (TDE) 91 is not completely matched or affected by a wire effect, greater phase errors may be easily generated by a multi-phase clock signal generator. In the meantime, it is very difficult technique to generate the same and minimum delay in continuous clock signals with multi-phase.

Therefore, designing a multi-phase clock generation system and a clock calibration method thereof to generate accurate multi-phase clock signals with the same time delay is a subject on market application that demands immediate attention and feasible solutions.

### SUMMARY OF THE INVENTION

In view of the aforementioned problem of the prior art, it is a primary objective of the present invention to provide a multi-phase clock generation system and a clock calibration method thereof to overcome the large time errors of the conventional multi-phase clock delay, and the extended duty cycle caused by the clock pulse passing through a plurality of buffer gates.

To achieve the foregoing objective, the present invention provides a multi-phase clock generation system, comprising an input module, a frequency division module and a control module. The input module is provided for inputting a reference clock signal with a clock period. The frequency division module according to the reference clock signal generates a phase clock signal with a frequency magnification relationship. The control module is provided for dividing a plurality of phase clock signals into a plurality of clock intervals, and each of the plurality of clock intervals has a phase time delay. The control module controls a first phase clock signal of the plurality of phase clock signals to align with a last phase clock signal. In addition, the control module sequentially arranges each of the plurality of phase clock signals according to the phase time delay.

Wherein, the multi-phase clock generation system further comprises a phase detection module for detecting the reference clock signal transmitted from the input module and the plurality of phase clock signals transmitted from the frequency division module.

Wherein, the frequency division module generates the phase clock signal, wherein the phase clock signal has the same period of the phase time delay.

Wherein, the multi-phase clock generation system further comprises a tunable delay element for setting a variable time delay according to the phase time delay and a clock circulation time.

Wherein, the tunable delay element generates an initial clock signal, and the control module controls each of the plurality of phase clock signals to align with the initial clock signal to calibrate the phase time delay of the plurality of phase clock signals.

Wherein, the control module is provided for locking the initial clock signal and the last phase clock signal to fine-tune each of the plurality of clock intervals sequentially.

Wherein, the tunable delay element comprises a plurality of input AND gates and a clock buffer, and the control module controls the plurality of input AND gates to reduce the pulse of the plurality of phase clock signals and controls the clock buffer to extend the pulse of the plurality of phase clock signals.

To achieve the aforementioned objective, the present invention further provides a clock calibration method applicable in a multi-phase clock generation system. The multi-phase clock generation system comprises an input module, a frequency division module and a control module. The clock calibration method comprises the steps of: providing the input module to input a reference clock signal with a clock period; using the frequency division module according to the reference clock signal to generate a plurality of phase clock signals with a frequency magnification relationship; generating a plurality of phase clock signals by a tunable delay element in the control module, and dividing the plurality of phase clock signals into a plurality of clock intervals, and each of the plurality of clock intervals has a phase time delay; controlling a first phase clock signal of the plurality of phase clock signals to align with a last phase clock signal by the control module; and sequentially arranging each of the plurality of phase clock signals by the control module according to the phase time delay.

In summation, the multi-phase clock generation system and the clock calibration method thereof in accordance with the present invention have one or more of the following advantages:

(1) The multi-phase clock generation system and the clock calibration method thereof can sequentially arrange each of a plurality of phase clock signals by using the control module according to the phase time delay.

(2) The multi-phase clock generation system and the clock calibration method thereof can use the tunable delay element to generate an initial clock signal and use the control module to control each of the plurality of phase clock signals to align with the initial clock signal.

(3) The multi-phase clock generation system and the clock calibration method thereof can use the control module to lock the initial clock signal and the phase clock signal to sequentially fine-tune each of the plurality of clock intervals and calibrate the phase time delay of the plurality of phase clock signals.

The technical characteristics of the present invention will become apparent with the detailed description of the preferred embodiments accompanied with the illustration of related drawings as follows.

### BRIEF DESCRIPTION OF THE DRAWINGS

FIG. 1 is a schematic view of a conventional multi-phase clock generator;

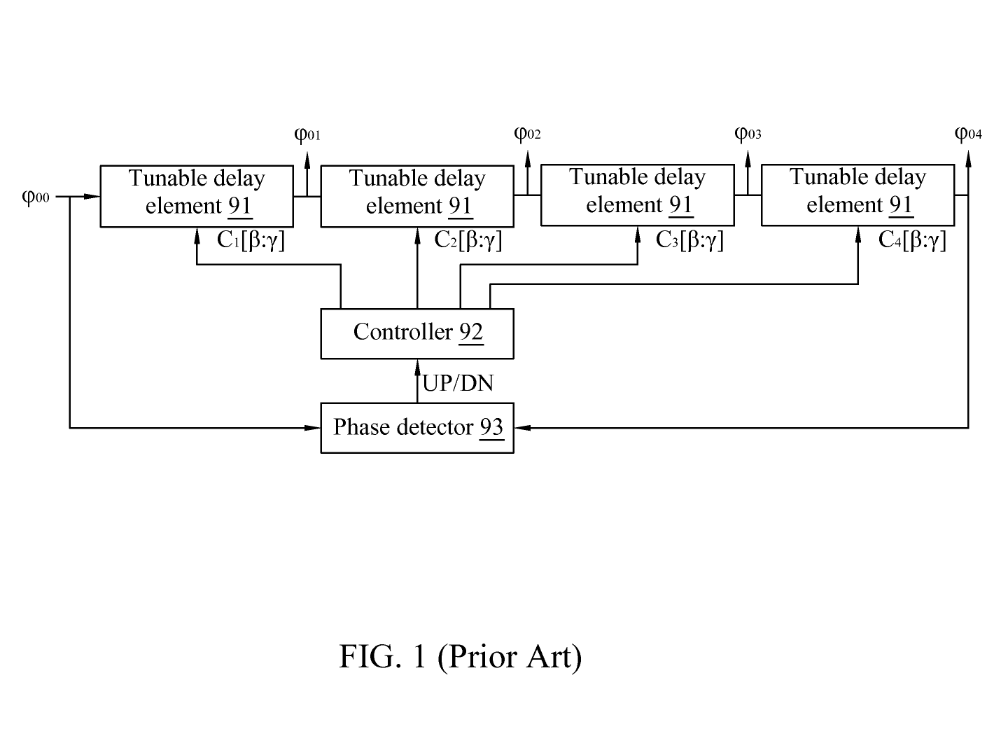

FIG. 2 is a schematic view of a conventional tunable delay element;

FIG. 3 is a block diagram of a multi-phase clock generation system in accordance with a first preferred embodiment of the present invention;

FIG. 4 is a flow chart of a clock calibration method in accordance with the first preferred embodiment of the present invention;

FIG. 5A is a first schematic view of a multi-phase clock generation system in accordance with a second preferred embodiment of the present invention;

FIG. 5B is a second schematic view of a multi-phase clock generation system in accordance with the second preferred embodiment of the present invention;

FIG. 6 is a schematic view of a tunable delay element in accordance with a preferred embodiment of the present invention; and

FIG. 7 is a flow chart of a clock calibration method in accordance with the second preferred embodiment of the present invention.

### DETAILED DESCRIPTION OF THE PREFERRED EMBODIMENTS

The following describes the multi-phase clock generation system and the clock calibration method thereof in accordance with the embodiments of the present invention with reference to the related figures. It is noteworthy to point out that same numerals are used for representing respective elements for the description of a preferred embodiment and the illustration of related drawings.

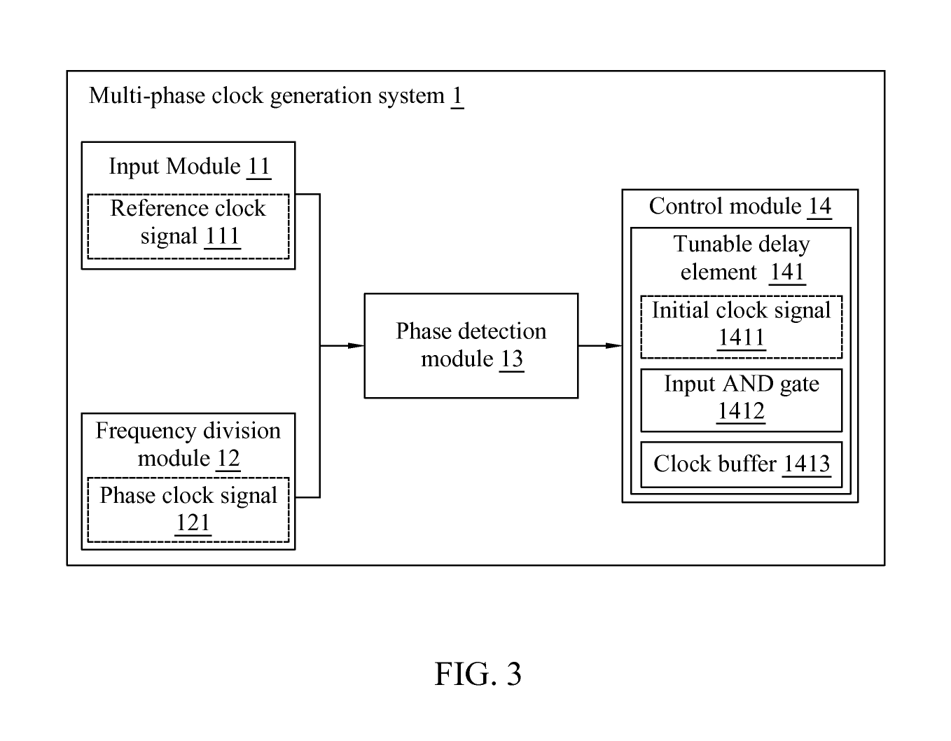

With reference to FIG. 3 for a block diagram of a multi-phase clock generation system in accordance with the first preferred embodiment of the present invention, the multi- phase clock generation system 1 comprises an input module 11, a frequency division module 12, a phase detection module 13 and a control module 14. The input module 11 is provided for inputting a reference clock signal 111 with a clock period. The frequency division module 12 according to the reference clock signal 111 is provided for generating a phase clock signal 121 with the same clock period. The phase detection module 13 is provided for detecting a reference clock signal 111 transmitted from the input module 11 and a plurality of phase clock signals 121 transmitted from the frequency division module 12. The control module 14 is provided for dividing the plurality of phase clock signals 121 into a plurality of clock intervals, and each of the plurality of clock intervals has a phase time delay. The control module 14 can sequentially arrange each of a plurality of phase clock signals 121 according to the phase time delay and control a first phase clock signal of the plurality of phase clock signals 121 to align with a last phase clock signal.

The control module 14 comprises a tunable delay element 141 for setting a variable time delay according to the phase time delay and a clock circulation time. The tunable delay element 141 may comprise a plurality of input AND gates 1412 and a clock buffer 1413, and the control module 14 controls the plurality of input AND gates 1412 to reduce the pulse of the plurality of phase clock signals 121 and controls the clock buffer 1413 to extend the pulse of the plurality of phase clock signals 121.

It is noteworthy to point out that the tunable delay element 141 can generate an initial clock signal 1411, and the control module 14 can control each phase clock signal 121 to align with the initial clock signal 1411 to calibrate the phase time delay of the plurality of phase clock signals 121. In the meantime, the control module 14 locks the initial clock signal 1411 and the last phase clock signal to fine-tune each of the plurality of clock intervals sequentially.

Even though the concept of the clock calibration method of the present invention has been described in the section of the multi-phase clock generation system of the present invention, a flow chart is provided to further illustrate the invention more clearly as follows.

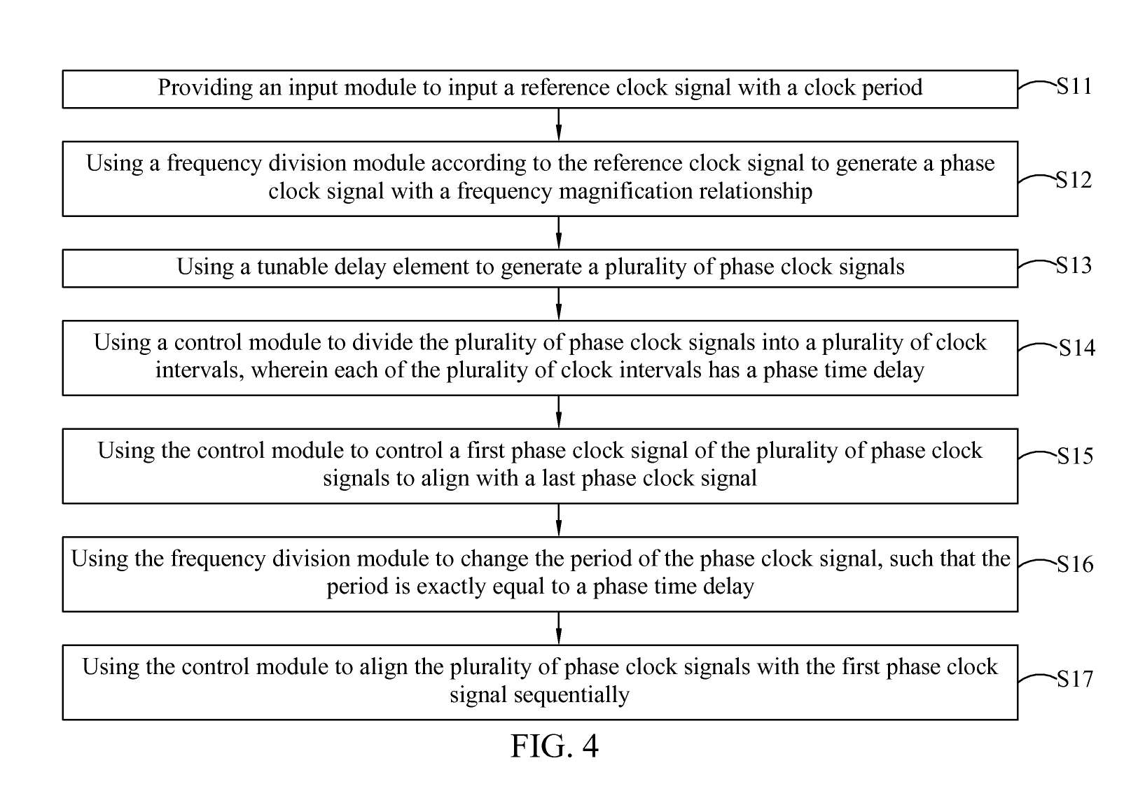

With reference to FIG. 4 for the flow chart of a clock calibration method in accordance with the first preferred embodiment of the present invention, the clock calibration method comprises the following steps:

step S11: Provide an input module to input a reference clock signal with a clock period.

step S12: Use a frequency division module according to the reference clock signal to generate a phase clock signal with a frequency magnification relationship.

step S13: Use a tunable delay element to generate a plurality of phase clock signals.

step S14: Use a control module to divide the plurality of phase clock signals into a plurality of clock intervals, wherein each of the plurality of clock intervals has a phase time delay.

step S15: Use the control module to control a first phase clock signal of the plurality of phase clock signals to align with a last phase clock signal.

step S16: Use the frequency division module to change the period of the phase clock signal, such that the period is exactly equal to a phase time delay.

step S17: Use the control module to align the plurality of phase clock signals with the first phase clock signal sequentially. Therefore, the plurality of phase time delays is adjusted to achieve the effect of a phase calibration.

Based on the first preferred embodiment, the present invention further provides a second preferred embodiment for illustrating the invention.

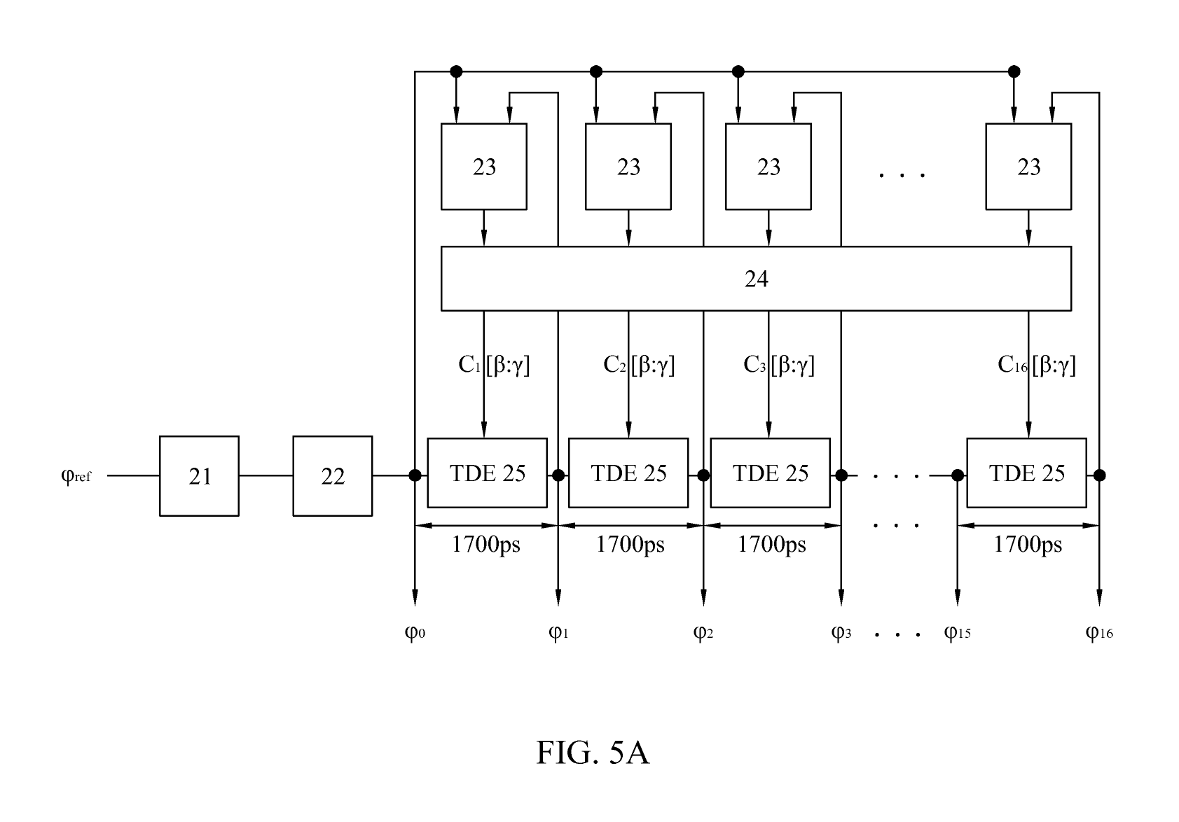

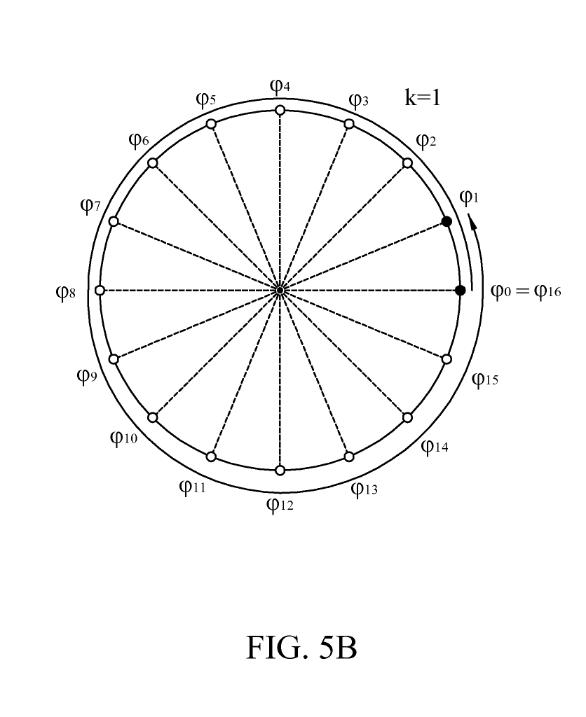

With reference to FIGS. 5A and 5B for first and second schematic views of a multi-phase clock generation system in accordance with the second preferred embodiment of the present invention respectively, the input module as shown in FIG. 5A inputs a reference clock signal φref, and the reference clock signal φref has a clock period or a clock circulation time of 1600 ps, and a clock frequency of 625 MHz. The frequency division module according to the reference clock signal φref generates a plurality of phase clock signals with a frequency magnification of 1, a clock period of 1600 ps, and a clock frequency of 625 MHz. The phase detection module 23 is used to detect the reference clock signal transmitted from the input module and a plurality of phase clock signals transmitted from the frequency division module. The control module 24 is used to divide the phase clock signal into 16 clock intervals, and each clock interval is equal to 100 ps. In this preferred embodiment, the phase clock signal comprises 16 phases, and each tunable delay element has a delay of (k*T+100 ps). The delay of (k*T+100 ps) is used for generating an output signal of the multi-phase clock generation system. Wherein, k is equal to 0 or any positive integer, and T is a clock period.

When k=1, a delay passing through each tunable delay element 25 is (1*1600+100)=1700 ps. In FIG. 5B, the phase time delay is equal to 1700 ps, and the reference clock signal φ0 may output a phase clock signal φ1 when passing through the tunable delay element TDE1. The control module 24 starts arranging the phase clock signal φ2 one by one from the phase clock signal φ1 to the phase clock signal φ16 according to the phase time delay of 1700 ps. It is noteworthy to point out that the frequency division module comprises a frequency divider 21 and an all-digital phase-locked loop (ADPLL) 22 and features frequency tracking with wide range, high speed and high resolution.

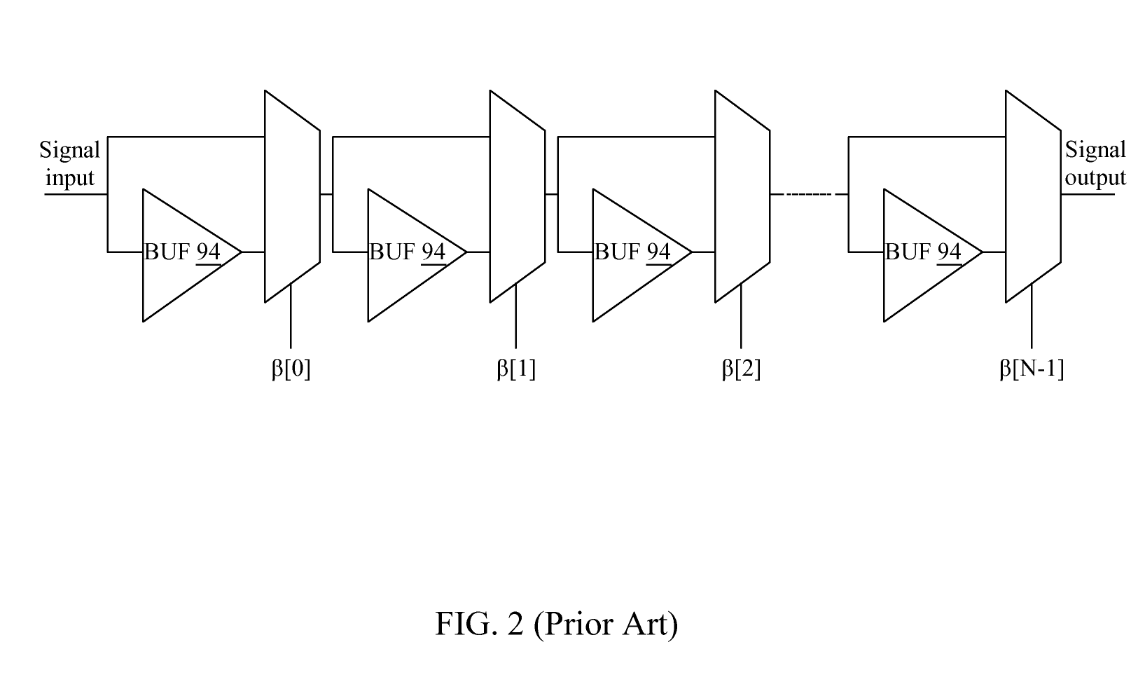

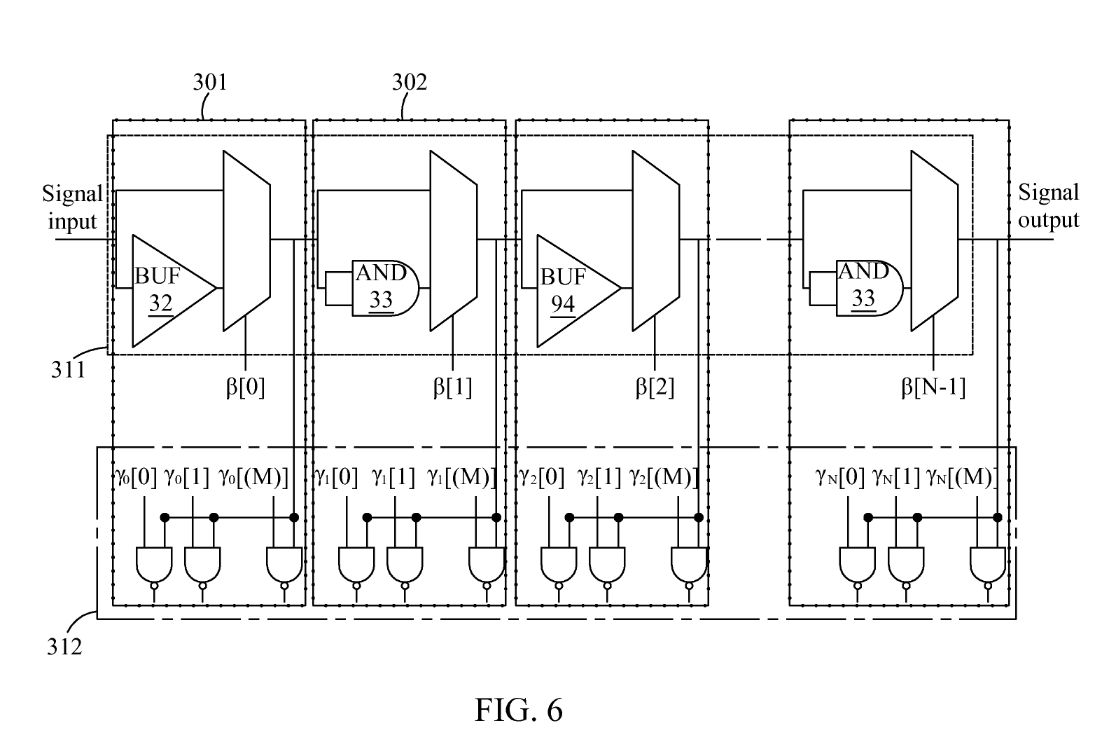

With reference to FIG. 6 for a schematic view of a tunable delay element in accordance with a preferred embodiment of the present invention, when a signal passes through too many buffer gates 94 in the tunable delay element, the clock pulse disappears completely as shown in FIG. 2. For example, if a signal passes through one buffer gate 94 in a 0.18 um-manifacturing process, the pulse of the signal is extended approximately by 10 ps. In other words, if a phase clock signal with a clock period of 1600 ps and a duty cycle of 50% is inputted, the pulse will disappear after the phase clock signal has passed through 80 buffer gates 94. In view of this problem, the tunable delay element of this preferred embodiment may comprise a two input AND gate 33 and a clock buffer 32. Starting from the left-side signal input terminal to the right-side signal input terminal of FIG. 6, a clock buffer 32 is disposed at an odd delay stage 301, and a two input AND gate 33 is disposed at an even delay stage 302. In the meantime, the circuit at the top is a beta part (β-part) 311 and can be used for coarse-tuning; and the circuit at the bottom is a gamma part (γ-part) 312 and can be used for fine-tuning. Therefore, the circuit comprising the beta part (β-part) 311 and the gamma part (γ-part) 312 features frequency tracking with wide range, high speed and high resolution.

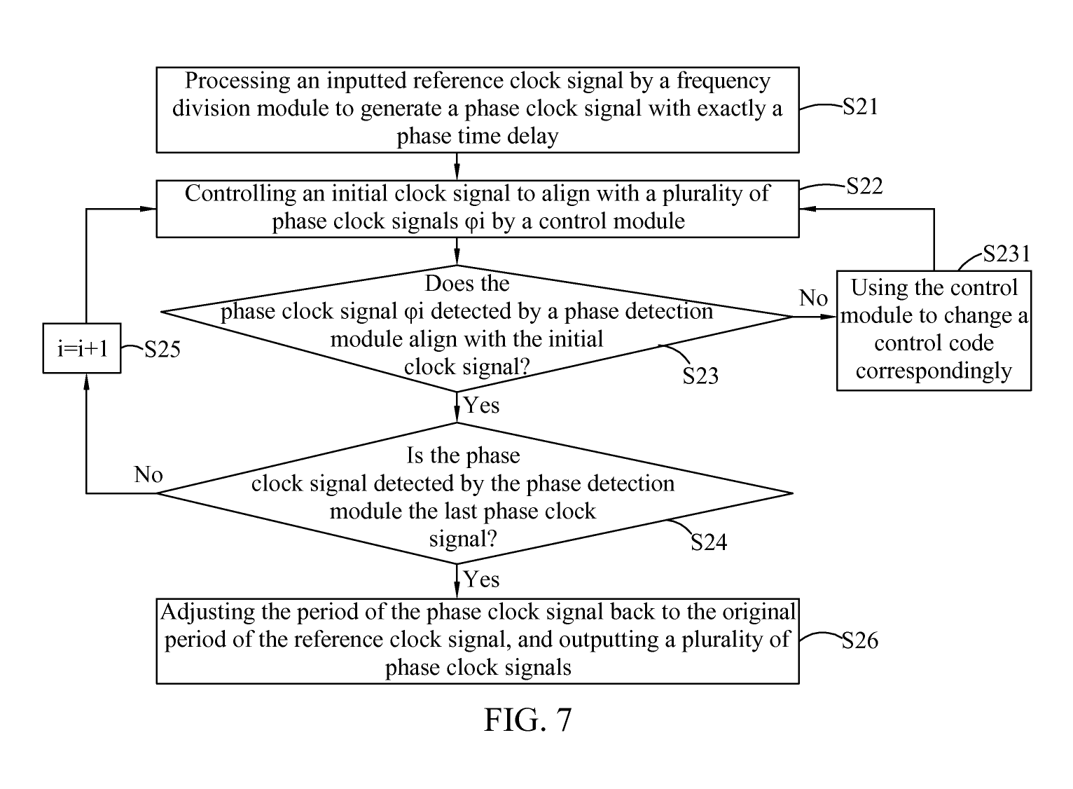

With reference to FIG. 7 for a flow chart of a clock calibration method in accordance with the second preferred embodiment of the present invention, the clock calibration method of the present invention is applied to the multi-phase clock generation system which includes an all-digital phase-locked loop (ADPLL) as shown in FIG. 5B, and the clock calibration method comprises the following steps:

step S21: Process an inputted reference clock signal by a frequency division module to generate a phase clock signal with exactly a phase time delay.

step S22: Control an initial clock signal to align with a plurality of phase clock signals φi by a control module.

step S23: Use a phase detection module to detect whether the phase clock signal φi aligns with the initial clock signal.

Carry out step S24 if the phase clock signal φi aligns with the initial clock signal; or else, carry out step S231 and return to step S22.

step S231: Use the control module to change a control code correspondingly.

step S24: Use a phase detection module to detect whether the phase clock signal is the last phase clock signal.

If yes, carry out step S26; or else, carry out step S25 and return to step S22.

step S25: i=i+1.

step S26: Adjust the period of the phase clock signal back to the original period of the reference clock signal, and output a plurality of phase clock signals.

In summation of the description above, the multi-phase clock generation system and the clock calibration method thereof of the present invention can use the control module to arrange each of the plurality of phase clock signals sequentially according to the phase time delay, use the tunable delay element to generate an initial clock signal, and use the control module to control each of the plurality of phase clock signals to align with the initial clock signal. In the meantime, the control module can be used to lock the initial clock signal and the phase clock signal to sequentially fine-tune each of the plurality of clock intervals and calibrate the phase time delay of the plurality of phase clock signals.

In summation of the description above, the present invention breaks through the prior art, achieves the expected improved effects, and complies with patent application requirements, and is thus duly filed for patent application. While the invention has been described by means of specific embodiments, numerous modifications and variations could be made thereto by those skilled in the art without departing from the scope and spirit of the invention set forth in the claims.

What is claimed is:

1. A multi-phase clock generation system, comprising:
an input module, inputting a reference clock signal with a clock period;
a frequency division module, according to the reference clock signal, generating a phase clock signal with a frequency magnification relationship; and
a control module, dividing the plurality of phase clock signals into a plurality of clock intervals, and each of the clock intervals having a phase time delay, and the control module controlling a first phase clock signal of the plurality of phase clock signals to align with a last phase clock signal;
wherein, the control module sequentially arranges each of the plurality of phase clock signals according to the phase time delay.

2. The multi-phase clock generation system of claim 1, further comprising a phase detection module for detecting the reference clock signal transmitted from the input module and the plurality of phase clock signals transmitted from the frequency division module.

3. The multi-phase clock generation system of claim 1, wherein the frequency division module generates the plurality of phase clock signals having a same period of the phase time delay.

4. The multi-phase clock generation system of claim 1, wherein the control module further comprises a tunable delay element setting a variable time delay according to the phase time delay and a clock circulation time.

5. The multi-phase clock generation system of claim 4, wherein the tunable delay element generates an initial clock signal, and the control module controls each of the plurality of phase clock signals to align with the initial clock signal to calibrate the phase time delay of the plurality of phase clock signals.

6. The multi-phase clock generation system of claim 5, wherein the control module locks the initial clock signal and the last phase clock signal to fine-tune each of the plurality of clock intervals sequentially.

7. The multi-phase clock generation system of claim 4, wherein the tunable delay element comprises a plurality of input AND gates and a clock buffer, and the control module controls the plurality of input AND gates to reduce a pulse of the plurality of phase clock signals and controls the clock buffer to extend the pulse of the plurality of phase clock signals.

8. A clock calibration method, applicable in a multi-phase clock generation system, and the multi-phase clock generation system comprising an input module, a frequency division module and a control module, and the clock calibration method comprising steps of:
providing the input module to input a reference clock signal with a clock period;
using the frequency division module according to the reference clock signal to generate a phase clock signal with a frequency magnification relationship;
dividing the plurality of phase clock signals into a plurality of clock intervals by the control module, wherein each of the plurality of clock intervals has a phase time delay;
controlling a first phase clock signal of the plurality of phase clock signals to align with a last phase clock signal by the control module; and
sequentially arranging each of the plurality of phase clock signals by the control module according to the phase time delay.

9. The clock calibration method of claim 8, further comprising a step of:
using a phase detection module to detect the reference clock signal transmitted from the input module and the plurality of phase clock signals transmitted from the frequency division module.

10. The clock calibration method of claim 8, wherein the frequency division module is provided for generating the plurality of phase clock signals, and the plurality of phase clock signals have a same period as the phase time delay.

11. The clock calibration method of claim 8, further comprising a step of;
using a tunable delay element to set a variable time delay according to the phase time delay and a clock circulation time.

12. The clock calibration method of claim 11, further comprising steps of:
using the tunable delay element to generate an initial clock signal; and
using the control module to control each of the plurality of phase clock signals to align with the initial clock signal to calibrate the phase time delay of the plurality of phase clock signals.

13. The clock calibration method of claim 12, further comprising a step of:
using the control module to lock the initial clock signal and the last phase clock signal to fine-tune each of the plurality of clock intervals sequentially.

14. The clock calibration method of claim 11, further comprising steps of:
using the control module to control a plurality of input AND gates to reduce a pulse of the plurality of phase clock signals; and
controlling a clock buffer by the control module to extend the pulse of the plurality of phase clock signals.
